(19) United States
(12) Patent Application Publication
(10) Pub. No.: US 2012/0225560 A1
(43) Pub. Date: Sep. 6, 2012

(54) MANUFACTURING METHOD OF INTEGRATED CIRCUITS BASED ON FORMATION OF LINES AND TRENCHES

(75) Inventors: Pascal Gouraud, Montbonnot St. Martin (FR); Bertrand Le-Gratiet, Grenoble (FR)

(73) Assignee: STMICROELECTRONICS (CROLLES 2) SAS, Crolles (FR)

(21) Appl. No.: 13/411,397

(22) Filed: Mar. 2, 2012

(30) Foreign Application Priority Data
Mar. 4, 2011 (FR) 1100662

(51) Int. Cl. H01L 21/311

(52) U.S. Cl. 438/703; 257/E21.257

(57) ABSTRACT

The disclosure relates to a method for etching a target layer, comprising: depositing a hard mask layer onto a target layer and onto the hard mask layer, a first photosensitive layer, exposing the first photosensitive layer through a first mask to transfer first patterns into the photosensitive layer, transferring the first patterns into the hard mask layer, depositing onto the hard mask layer etched a second photosensitive layer, exposing the second photosensitive layer through a second mask to transfer second patterns into the second photosensitive layer, transferring the second patterns into the hard mask layer by etching this layer, and transferring the first and second patterns into the target layer through the hard mask, the second patterns forming lines, and the first patterns forming trenches cutting the lines in the hard mask.

### BACKGROUND

1. Technical Field

The present disclosure relates to a method for manufacturing electronic components on a semiconductor substrate. It relates in particular to photolithography processes implementing successive steps of patterning in a layer called “hard mask” deposited onto a target layer.

2. Description of the Related Art

Photolithography processes consist in etching patterns using a layer in a photosensitive material, such as a photoresist deposited onto a target layer formed on a substrate. A layer called “hard mask” may be deposited onto the target layer before depositing the photoresist layer. The pattern to be transferred to the target layer is then transferred to the photoresist layer by photolithography, then by etching to the hard mask layer and target layer. A transfer of patterns to the photoresist layer generally consists in exposing the layer in a photolithography machine to a beam of particles through a mask having the patterns to be transferred, then removing the exposed parts (in the case of a positive photoresist) or the not exposed parts (in the case of a negative photoresist) using a developing solvent. The minimum size for the patterns susceptible of being transferred to a photosensitive layer is called “critical dimension” (CD) and corresponds for example to the width of a pattern line. The critical dimension depends on features of the photolithography exposition machine and in particular the optical projection device, and on features of the exposition, development and the photosensitive material used.

To reduce even more the critical dimensions of patterns susceptible of being etched into a target layer without replacing the photolithography machine, several methods of multiple patterning have been developed. Some of these methods include successively transferring several patterns to a hard mask layer formed on the target layer, by depositing a new photoresist layer onto the hard mask layer between each transfer. According to a multiple patterning method described in the patent U.S. Pat. No. 6,787,469, line patterns of a first mask, have parallel lines having the critical dimension of the photolithography process. Cutting patterns of a second mask, have shapes that remove a part of the line patterns, and in particular cut some lines formed by the line patterns. This method is used in particular to form gates of CMOS transistors in polysilicon, which may currently reach a minimum width of around 30 nm.

Such a photolithography process using multiple patterning is shown by FIGS. 1A to 1F and 2A to 2C. FIGS. 1A to 1F show in transversal section a part of a multi-layer structure formed from a wafer in a semiconductor material, at different steps of a photolithography process. FIGS. 2A to 2C show in top views a part of the multi-layer structure at some steps of the photolithography process. In FIG. 1A, the multi-layer structure comprises a substrate SB on which a target layer TL is formed. The target layer TL is covered by a hard mask layer HM, and the layer HM is covered by a photoresist layer PR. In FIG. 1B, line patterns formed on a first mask have been transferred to the layer PR by a photolithography machine. FIG. 2A shows the shape of the line patterns transferred to the layer PR. In FIG. 2A, the line patterns form parallel lines L1, L2, L3, among which two adjacent lines L1, L2 are linked by a bridge. The lines L1, L2, L3 formed in the processed layer have a width D which may match the critical dimension of the photolithography process. This width is decisive for the electrical performances of components which will be formed by the line patterns in the target layer TL.

In FIG. 1C, the line patterns have been transferred to the layer HM by an etching process and the layer PR has been removed. In FIG. 1D, the layer HM is covered again by a photoresist layer PR′. In FIG. 1E, cutting patterns formed on a second mask have been transferred to the layer PR′ by the photolithography machine. FIG. 2B shows the shape of the cutting patterns transferred to the layer PR′. In FIG. 2B, the cutting patterns form rectangular trenches R1, R2 provided to cut the lines L1, L2, L3 which have been formed in the layer HM. The trenches R1, R2 have a width D1 which may be higher than the critical dimension CD. Contrary to the line patterns, the cutting patterns have dimensions which are not decisive on the electrical performances of the components formed by the line patterns. The only important thing is that the cutting patterns cut the lines in wanted locations to form different electronic components.

In FIG. 1F, the layer HM has been etched at the shape of the patterns transferred to the layer PR′, the layer PR′ has been removed, and the target layer TL has been etched at the shape of the patterns transferred to the layer HM. FIG. 2C has the shape of the patterns thus formed in the layers HM and TL. These patterns correspond to the lines L1, L2, L3 from which the rectangular areas R1, R2 have been removed. The hard mask layer HM may then be totally removed.

In practice, all the processes between the etching of the lines and the final etching of the hard mask layer have an effect of reducing the critical dimensions of the patterns formed in this layer and therefore in the target layer. Each etching process is therefore followed by a meteorology step during which different parameters including the critical dimensions are measured. The photolithography process forming the line patterns in the layer PR may be adapted if the critical dimensions measured varies from those to be reached. Likewise, the measures obtained after the first etching of the hard mask layer HM (FIG. 1C) are taken into account during the second etching process to make possible corrections. Final measurements make it possible to determine if the patterns are properly transferred to the target layer TL.

All the processing steps affect the critical dimensions except for the photolithography step of the layer PR′. This step may therefore be performed with a photolithography machine less precise and therefore less expensive than that which are used for the other photolithography steps. However, a change of photolithography machine during a multiple patterning process at critical dimension raises several sensitive issues and in particular issues regarding the alignment of the two mask patterns to be transferred onto the semiconductor wafer. During the process of the structures at critical dimension, the measures obtained during the first hard mask etching process are used to adjust the second hard mask etching process. If a machine change occurs between these two hard mask etching processes, these measures must be saved and introduced into the machine performing the second hard mask etching process.

It is therefore desirable to simplify such a multiple patterning method. It is also desirable to reduce the utilization time of an expensive photolithography machine, in particular by making it possible to use a less expensive photolithography machine for the processes not involved at critical dimension.

### BRIEF SUMMARY

Embodiments relate to a method for etching a target layer, comprising: depositing a hard mask layer on a target layer and on the hard mask layer, a first layer in a photosensitive material, exposing the first photosensitive layer to a beam of particles through a first mask (MSK1) to transfer first patterns, forming the first patterns in the photosensitive layer, transferring the first patterns into the hard mask layer by etching this layer through the first photosensitive layer, depositing onto the hard mask layer etched a second layer in a photosensitive material, exposing the second photosensitive layer to a beam of particles through a second mask to transfer second patterns, forming the second patterns in the second photosensitive layer, transferring the second patterns into the hard mask layer by etching this layer through the second photosensitive layer, and transferring the first and second patterns into the target layer by etching this layer through the hard mask layer, wherein the second patterns form lines in the hard mask layer, and the first patterns form trenches cutting the lines in the hard mask layer.

According to an embodiment, between the steps of second etching of the hard mask layer and etching of the target layer, the method comprises: depositing onto the hard mask layer etched a third layer in a photosensitive material, exposing the third photosensitive layer to a beam of particles through a third mask to transfer third patterns, forming the third patterns in the third photosensitive layer, and transferring the third patterns into the hard mask layer by etching this layer through the third photosensitive layer, the target layer being etched by receiving the first, second and third patterns formed in the hard mask layer, the third patterns forming lines cut by the first patterns.

According to an embodiment, one or each of the photosensitive layers is directly deposited onto the hard mask layer, previously etched or not, the photosensitive layer having a reflection coefficient of the beam of particles lower than 1%, and a plane upper face, and covers the hard mask layer without trapping gas bubbles.

According to an embodiment, the upper surface of one or each of the photosensitive layers has a height variation lower than 20%, and preferably, lower than 15%.

According to an embodiment, an additional layer is directly deposited onto the hard mask layer, previously etched or not, one or each of the photosensitive layers being deposited onto the additional layer, the method comprising etching the additional layer to transfer the patterns formed in the photosensitive layer to the additional layer.

According to an embodiment, the additional layer has a reflection coefficient of the beam of particles lower than 1%, and a plane upper face, and covers the hard mask layer without trapping gas bubbles.

According to an embodiment, the upper surface of one or each of the photosensitive layers has a height variation lower than 20%, and preferably, lower than 15%.

According to an embodiment, one or each of the photosensitive layers is deposited onto a second hard mask layer, the second hard mask layer being deposited onto the additional layer, the method comprising etching the second hard mask layer to transfer the patterns formed in the photosensitive layer to the hard mask layer.

According to an embodiment, the target layer is a layer provided to form gates of CMOS transistors.

### BRIEF DESCRIPTION OF THE SEVERAL VIEWS OF THE DRAWINGS

Embodiments of the disclosure will be described hereinafter, in relation with, but not limited to the appended figures wherein:

FIGS. 1A to 1F previously described show in transversal section a part of a multi-layer structure formed from a wafer in a semiconductor material, at different steps of a photolithography process.

FIGS. 2A to 2C previously described show in top views the part of the multi-layer structure at some steps of the photolithography process.

FIG. 3 shows a sequence of steps of a photolithography process, according to one embodiment,

FIGS. 4A to 4F show in transversal section a part of a multi-layer structure formed from a wafer in a semiconductor material, at different steps of the photolithography process,

FIGS. 5A to 5C show in top views the part of the multi-layer structure at some steps of the photolithography process,

FIG. 6 shows a part of the multi-layer structure formed during a photolithography process, according to another embodiment,

FIGS. 7A to 7E show in transversal section a part of the multi-layer structure, at different steps of a photolithography process, according to another embodiment,

FIGS. 8A to 8D show in top views the multi-layer structure at some steps of the photolithography process.

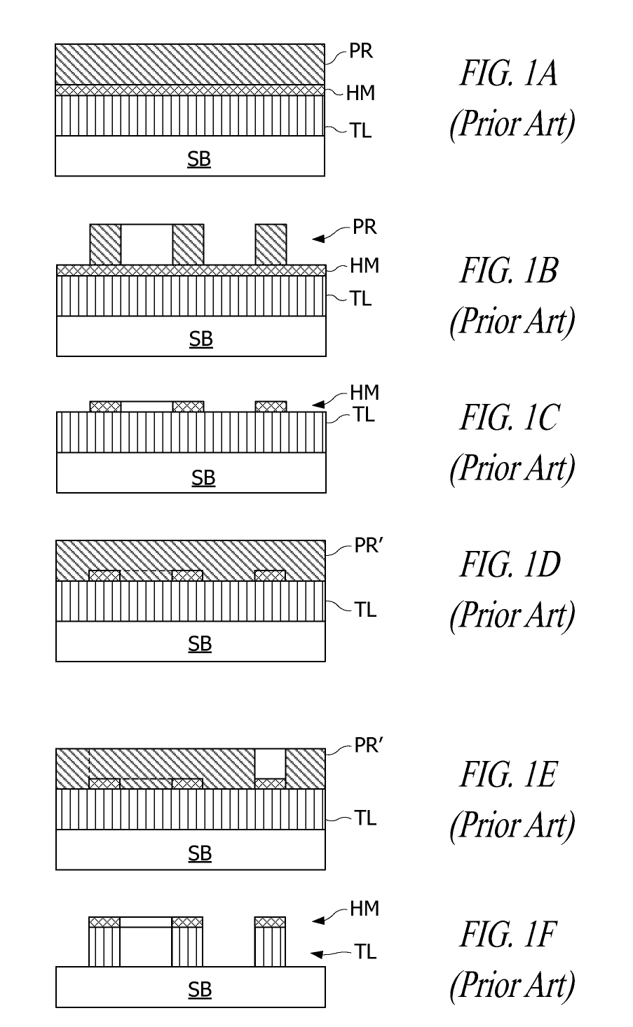

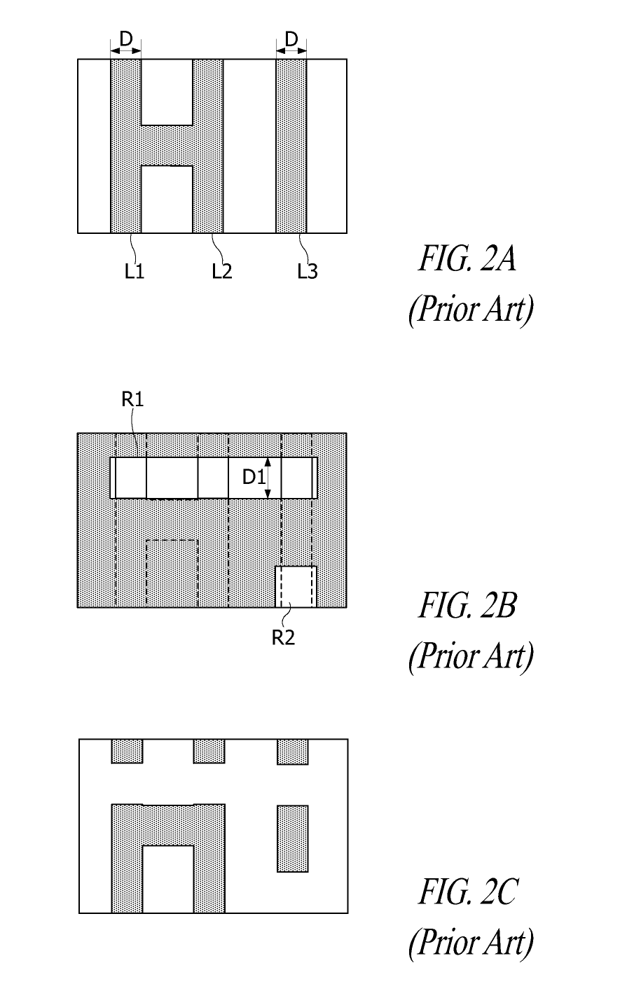

### DETAILED DESCRIPTION

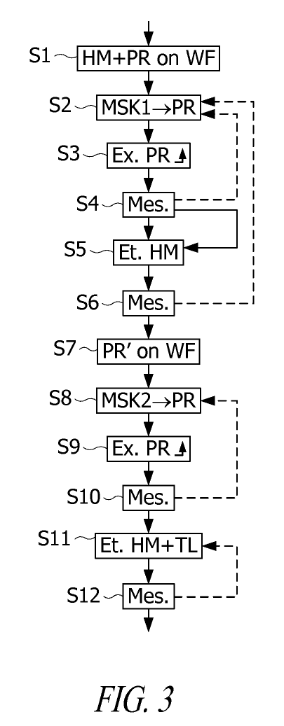

FIG. 3 shows a sequence of steps of a photolithography process of a target layer TL in a multi-layer structure formed on a substrate SB for example of a semiconductor material. The sequence of steps comprises steps S1 to S12. The target layer is the layer to which patterns must be transferred for example to make electronic components of integrated circuit.

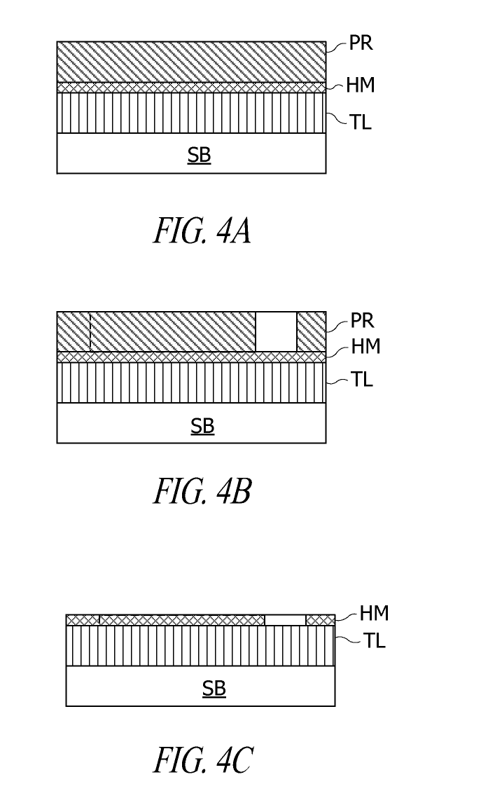

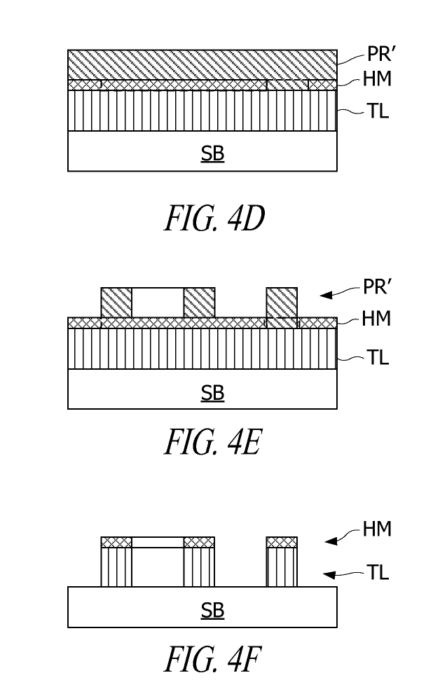

At step S1, a hard mask layer HM and a layer of a photosensitive material PR are successively deposited onto the target layer TL. FIG. 4A shows a multi-layer structure which may be obtained at the end of step S1. In FIG. 4A, the multi-layer structure comprises the target layer TL to be processed by the photolithography process, the target layer being formed on the substrate SB. The layer TL is covered by the layer HM, and the layer HM is covered by the layer PR.

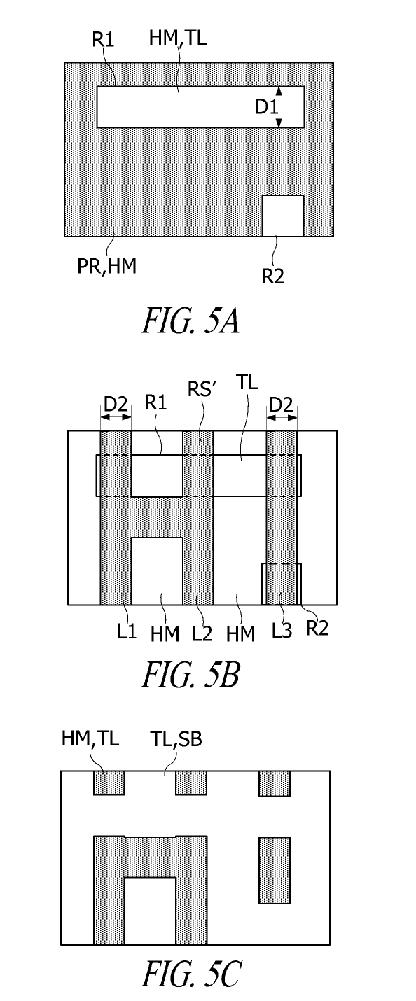

At step S2, the layer PR is subjected to a beam of particles (photons, electrons, . . . ) through a mask MSK1. Step S3 is a development step during which the parts exposed (or not exposed) by the photolithography machine through the mask MSK1 are removed. FIG. 4B shows the multi-layer structure after the transfer of the patterns of the mask MSK1 to the layer PR. FIG. 5A shows the shape of the patterns transferred to the layer PR. According to one embodiment, the patterns transferred by the mask MSK1 to the layer PR are cutting patterns allowing trenches to be formed in the hard mask layer HM. The cutting patterns have minimum dimensions which may be higher than the critical dimensions of the photolithography process. In the example shown by FIG. 5A, the patterns of the mask MSK1 transferred to the layer PR comprise two trenches R1, R2 of rectangular shape which width D1 may be higher than the critical dimensions of the photolithography machine used.

The following step S4 is a meteorology step allowing the quality of the transfer from the mask MSK1 to the layer PR to be controlled. If, on a batch of wafers, the patterns R1, R2 have dimensions higher or lower than desired dimensions, the photolithography process performed at steps S2, S3 may be readjusted for a following batch of wafers. This readjustment according to measures forms a regulation loop (here of Run to Run type) which allows the global quality of the batches of wafers thus produced to be improved. The measures obtained at step S4 on a given batch of wafers, may also be used to adjust on this same batch of wafers, the etching parameters of the hard mask layer at the following step S5. This readjustment performed at a following step (usually called “Feed Forward”), based on measures obtained at a previous step, is also important for the control of fabrication processes.

The shapes and dimensions of the patterns R1, R2 thus transferred are not decisive for the quality of the final result of the process of the target layer TL. At step S5, the layer HM is etched through the layer PR, so as to transfer the patterns formed in the layer PR to the layer HM, and the layer PR is removed. FIG. 4C shows the multi-layer structure at the end of step S5. The following step S6 is a meteorology step allowing the dimensions of the patterns transferred to the hard mask layer HM to be controlled. If the measures obtained at step S6 are not satisfying, the photolithography process performed at steps S2, S3 may be readjusted for a following batch of wafers.

At step S7, a new photoresist layer PR′ is deposited onto the layer HM which has been etched at step S5. FIG. 4D shows the multi-layer structure at the end of step S7. This step is for example performed by centrifugation, by depositing the liquid photoresist at the center of a semiconductor wafer forming the substrate SB, and by rotating the wafer. At step S8, the photoresist layer PR′ is subjected to a beam of particles (photons, electrons, . . . ) through a mask MSK2.

Step S9 is a development step during which the parts exposed (or not exposed) by the photolithography machine through the mask MSK2 are removed. FIG. 4E shows the multi-layer structure after the transfer of the patterns of the mask MSK2 to the layer PR′. According to one embodiment, the patterns transferred by the mask MSK2 to the layer PR′ are line patterns having minimum dimensions which may be equal to the critical dimensions of the photolithography process. FIG. 5B shows the shape of the patterns transferred to the layer PR′. In FIG. 5B, the patterns transferred have lines L1, L2, L3, among which the adjacent lines L1, L2 are linked by a bridge. The lines L1, L2, L3 formed in the layer PR′ have a width D2 which may be equal to the critical dimensions of the photolithography process. This width is decisive for the electrical performances of components which will be formed by the line patterns in the target layer TL. On the contrary, the cutting patterns R1, R2 have dimensions which are not decisive for the electrical performances of the components formed by the line patterns. The only important thing is that the cutting patterns cut the lines in wanted locations to form different electronic components.

The following step S10 is a meteorology step allowing the dimensions of the patterns transferred to the layer PR′ to be controlled. If at step S10, the dimensions of the patterns transferred into the layer PR′ are superior or inferior to desired dimensions, the photolithography process performed at steps S8, S9 may be readjusted for a following batch of wafers. At step S11, the layer HM is etched at the shape of the patterns transferred into the layer PR′ and the layer PR′ is removed. If at step S10, the dimensions of the patterns transferred into the layer PR′ are superior or inferior to desired dimensions, the etching process of the layer HM may be extended. The target layer TL is then etched at the shape of the patterns R1, R2, L1, L2, L3 transferred to the layer HM. FIG. 4F shows the multi-layer structure at the end of the etching process at step S11. FIG. 5C has the shape of the patterns formed in the layers HM and TL. These patterns correspond to the lines L1, L2, L3 from which the rectangular areas R1, R2 are removed. The hard mask layer HM may then be totally removed. The following step S12 is a meteorology step which aim is to determine in particular if the dimensions of the patterns transferred to the target layer TL correspond to those desired. If the measures obtained at step S12 are not satisfying, the photolithography processes performed at steps S2, S3 and S8, S9 may be readjusted for a following batch of wafers.

The etching processes of the hard mask layer have an effect of reducing the critical dimensions of the patterns formed in this layer and therefore in the target layer. Thus, in one embodiment, the patterns L1, L2, L3 transferred into the layer PR′ have a critical dimension of 52 nm, and when they are transferred to the target layer TL, they may reach a dimension of 34 nm. The meteorology steps are for example performed using a scanning electron microscope SEM, or by scatterometry. The patterns thus formed in the target layer TL allow for example gates of CMOS transistors to be made, the layer TL then being polysilicon, but the target layer could be of other materials, such a metal or single-crystal semiconductor. The width D2 of the lines L1, L2, L3 corresponds to the length of the gates of the transistors thus formed. These lines therefore have a dimension (their width) which is decisive for the electrical performances of these transistors. On the contrary, no dimension of the patterns R1, R2 is decisive for the electrical performances of these transistors. The presence of the trenches R1, R2 separates the gates of the transistors collectively formed by the lines L1, L2, L3.

It is observed that the formation of patterns L1, L2, L3 in the hard mask layer HM is not affected by the presence of the trenches R1, R2 previously formed in the layer HM. Indeed, so that a photosensitive layer is properly exposed, the surface to be exposed should be very planar. Depositing a photosensitive layer on the slightest relief is therefore to be avoided in particular when the structures to be formed are very critical regarding their dimensions. In the current case, depositing the photosensitive layer PR′ directly onto the trenches R1, R2 formed in the layer HM was therefore to be avoided. Depositing onto the hard mask layer HM a layer having planarizing and antireflective properties should be sufficient to avoid the presence of relief (trenches R1, R2) in the layer HM. Thus, the photoresist used to form the layer PR′ may be chosen so as to cover the layer HM by penetrating into the trenches R1, R2 formed at step S5 without trapping gas bubbles, and to have an upper face planar and antireflective enough, at the end of its deposit onto the layer HM not to affect the following processes of photolithography and etching of the hard mask layer HM. In practice, it is desirable that the layer deposited onto the hard mask layer HM be planar enough for its upper surface to have, in particular on each side of the edge of a trench pattern R1, R2, a variation of its height lower than 20%, and preferably, lower than 15%, this variation being expressed in percentage of the depth of field of the photolithography process used. For example, for a photolithography process having a depth of field of 120 nm and a hard mask 30 nm thick, the local height variations resulting from the presence of the trenches would represent 25% of the depth of field. In the absence of layer having sufficient planarizing properties, the upper surface of the photoresist PR′ would have local variations too, representing 25% of the depth of field, which is unacceptable in practice for a critical photolithography step. On the other hand, a photoresist layer making it possible to reduce to less than 20 nm at its upper surface, the height variations of 30 nm at its lower surface resulting from the trenches, allows the local height variations of the upper surface of the photoresist to be reduced to less than 17% of the depth of field, which is acceptable.

The method which has been described has the advantage of successively performing the critical photolithography and etching processes (steps S7, S8, S9 and S11), i.e., decisive for the electrical performances of the electronic components made. In prior art, the photolithography and etching processes of the trenches were performed between the final photolithography and etching processes of the electrically critical structures. This advantage offers the possibility of performing the critical photolithography and etching processes without changing of etching machine. This also makes it possible to optimally implement regulation loops of feed forward type. This method also has the advantage of having to perform only two critical dimensional controls instead of three like in the method of prior art. Indeed, the dimensional control performed at step S4 does not concern critical patterns regarding the formation of the electronic components.

In practice, to reach a line width D2 of around 30 nm, the photoresists used have planarizing and antireflective properties. The planarizing and antireflective properties of the photoresists are generally not sufficient to reach critical dimensions lower than 100 nm. The antireflective property is characterized by a reflection coefficient of the beam of particles emitted by the photolithography machine lower than 1%, or 0.5%. This property may be obtained using a Bottom Anti-Reflective Coating BARC formed under the photoresist layer PR′ and possibly under the layer PR. The coating BARC may be made by coating an antireflective photoresist, or by depositing (CVD—Chemical Vapor Deposition, PECVD—Plasma-Enhanced Chemical Vapor Deposition, . . . ) an organic layer (for example in amorphous carbon) and/or a dielectric layer (for example in silicon oxide SiO₂, silicon nitride Si₃N₄, . . . ).

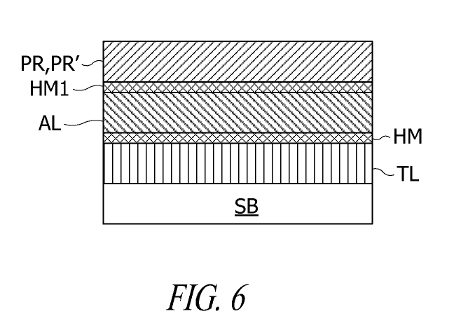

Another solution is to associate the layers PR and PR′ with a hard mask layer and a layer in a planarizing and antireflective material, not necessarily photosensitive. FIG. 6 shows a multi-layer structure which may be formed at steps S1 and S7. In FIG. 6, the hard mask layer HM deposited onto the target layer TL, is covered by a layer AL of an antireflective and planarizing material, for example carbon-based. The layer AL is covered by a hard mask layer HM1, onto which is deposited the photoresist layer PR, PR′. The layers HM and HM1 may be formed in silicon oxide, silicon nitride, or titanium nitride TiN. The layer AL is made of a material able to cover the layer HM by penetrating into the trenches formed at step S5 without trapping gas bubbles, and to have a planar upper face at the end of its deposit onto the layer HM. The layer AL also has antireflective properties, i.e., a reflection coefficient of the beam of particles emitted by the photolithography machine lower than 1%. The layer AL may comprise an organic film (for example of carbon) deposited by centrifugation or by CVD or PECVD. The layers AL, HM1 and PR are formed again at each pattern transfer from the mask to the layer HM. The different layers deposited onto the target layer TL may be formed by PVD (Physical Vapor Deposition) or CVD, or by centrifugation. The development processes of the photosensitive layers PR, PR′ after exposure, and the etching processes of the hard mask layers HM, HM1, of the layer AL and the target layer TL, are adapted to the dimensions to be obtained and the materials to be etched, and may implement known techniques.

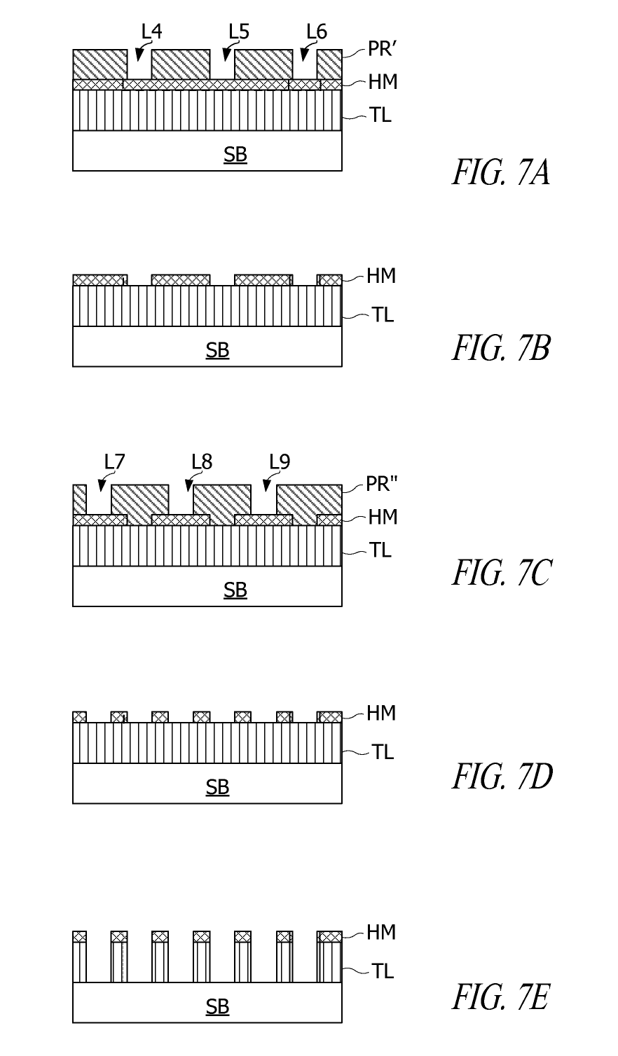

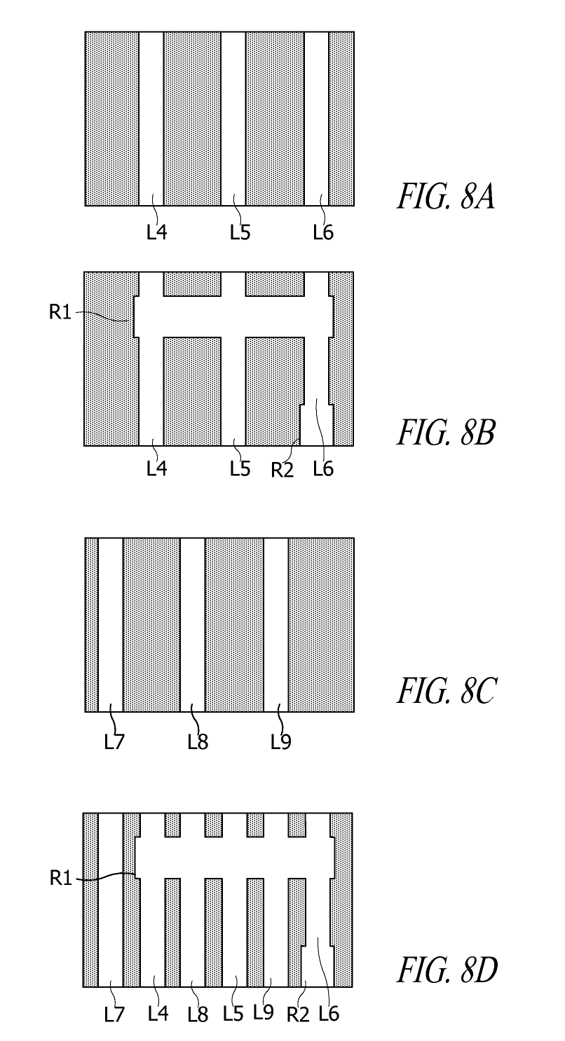

To increase the density of the structures transferred to the layer HM, steps S7 to S10 may be repeated with masks forming complementary patterns such that the combination of masks allows high density structures to be formed. These high density structures are generally cut after being formed in the hard mask layer and before their final transfer to the layer to be etched. According to one embodiment, the steps of forming areas to be suppressed (trenches) in the hard mask layer are performed before the multiple steps of forming high density structures (lines). FIGS. 7A to 7E show different steps of a photolithography process allowing the patterns of three masks to be successively transferred. As previously, steps S1 to S6, corresponding to FIGS. 4A to 4C, are performed to transfer the patterns R1, R2 shown in FIG. 5A to the hard mask layer HM. Then, a new photosensitive layer PR′ is deposited onto the layer HM. Patterns such as those shown in FIGS. 7A, 8A are transferred to the layer PR′. In FIGS. 7A, 8A, the patterns comprise three parallel lines L4, L5, L6 having a width that may be equal to the critical dimension of the photolithography process. In FIG. 7A, the lines L5, L6, L7 form trenches in the layer PR′. The patterns formed in the layer PR′ are then transferred to the layer HM, as shown by FIG. 7B. According to FIG. 8B, the layer HM is etched both by the trenches corresponding to the lines L4, L5, L6 and the trenches corresponding to the rectangular areas R1, R2 (FIG. 5A).

In FIG. 7C, a new layer in a photosensitive material PR″ is then deposited onto the layer HM, and new patterns are transferred to the layer PR″. According to FIG. 8C, the new patterns transferred comprise parallel lines L7, L8, L9 which are transferred to the layer PR″ forming trenches between the lines L4, L5, L6. The layer PR″ allows the patterns L7, L8, L9 to be transferred to the layer HM as shown in FIGS. 7D and 8D. Thus, in FIG. 8D, the layer HM gathers the trenches R1, R2, and the lines L4 to L9. The target layer TL is then etched with the patterns formed in the layer HM. The lines between the trenches formed by the lines L4 to L9 form for example gates of CMOS transistors.

The method which has just been described (implementing three mask projections) thus allows a line spacing to be reached, which is twice smaller than that obtained by the method previously used, implementing two mask projections (FIGS. 4A to 4F and 5A to 5C). Admittedly, if the dimensions of the patterns allow it, it may easily be considered to perform other pattern etchings to increase the density of the patterns transferred to the target layer. In these multiple structure definitions, the definition of the areas to be cut in the hard mask layer is performed before defining the structures having critical dimensions.

It will be clear to those skilled in the art that the present disclosure is susceptible of various embodiments and applications. In particular, the disclosure is not limited to etching a layer of polysilicon to form gates of transistors, but may be applied to etching hard mask layers to perform doping of areas of the substrate or a layer in a semiconductor material, or etching various layers formed on a wafer in a semiconductor material.

The various layers shown in FIG. 6 may be deposited only to perform the second etching of the hard mask layer HM and possible following etchings.

The present disclosure is not limited either to patterns of rectangular shapes for line and cutting patterns. Other more complex polygonal pattern shapes may admittedly be transferred to the hard mask layer and the target layer.

The various embodiments described above can be combined to provide further embodiments. These and other changes can be made to the embodiments in light of the above-detailed description. In general, in the following claims, the terms used should not be construed to limit the claims to the specific embodiments disclosed in the specification and the claims, but should be construed to include all possible embodiments along with the full scope of equivalents to which such claims are entitled. Accordingly, the claims are not limited by the disclosure.

1. A method for etching a target layer, comprising:
depositing a first hard mask layer on a target layer and on the first hard mask layer, a first photosensitive layer;
transferring first patterns to the first photosensitive layer by exposing the first photosensitive layer to a beam of particles through a first mask;
forming the first patterns in the photosensitive layer;
transferring the first patterns into the first hard mask layer by etching the first hard mask layer through the first photosensitive layer;
depositing onto the etched first hard mask layer a second photosensitive layer;
transferring second patterns to the second photosensitive layer by exposing the second photosensitive layer to a beam of particles through a second mask;
forming the second patterns in the second photosensitive layer;
transferring the second patterns into the first hard mask layer by etching first the hard mask layer through the second photosensitive layer; and
transferring the first and second patterns into the target layer by etching the target layer through the first hard mask layer,
wherein the second patterns form lines of the first hard mask layer, and the first patterns form trenches through the lines of the first hard mask layer.

2. A method according to claim 1, comprising, after transferring the second patterns into the first hard mask layer and before etching the target layer:
depositing onto the etched first hard mask layer a third photosensitive layer,
transferring third patterns to the third photosensitive layer by exposing the third photosensitive layer to a beam of particles through a third mask,
forming the third patterns in the third photosensitive layer, and
transferring the third patterns into the first hard mask layer by etching the first hard mask layer through the third photosensitive layer,
the target layer being etched according to the first, second and third patterns formed in the first hard mask layer, the third patterns forming lines of the target layer that are spaced apart by the first patterns.

3. A method according to claim 1, wherein one or each of the photosensitive layers is directly deposited onto the first hard mask layer, the photosensitive layer having a reflection coefficient of the beam of particles lower than 1%, and a planar upper face, and covers the first hard mask layer without trapping gas bubbles.

4. A method according to claim 3, wherein an upper surface of at least one of the photosensitive layers has a height variation lower than 20%.

5. A method according to claim 1, further comprising:
depositing an additional layer onto the first hard mask layer, at least one of the photosensitive layers being deposited onto the additional layer; and
transferring to the additional layer the patterns formed in the at least one photosensitive layer deposited onto the additional layer by etching the additional layer.

6. A method according to claim 5, wherein the additional layer has a reflection coefficient of the beam of particles lower than 1%, and a planar upper face, and covers the first hard mask layer without trapping gas bubbles.

7. A method according to claim 5, wherein an upper surface of at least one of the photosensitive layers has a height variation lower than 20%.

8. A method according to claim 7, further comprising:
depositing a second hard mask layer on the additional layer, wherein at least one of the photosensitive layers is deposited onto the second hard mask layer; and
transferring to the second hard mask layer the patterns formed in the at least one photosensitive layer deposited on the second hard mask layer by etching the second hard mask layer.

9. A method according to claim 1, wherein etching the target layer includes forming gates of CMOS transistors.

10. A method, comprising:
forming on a target layer a patterned first hard mask layer with first patterns;
depositing a first photosensitive layer onto the patterned to the additional layer hard mask layer;
forming second patterns in the first photosensitive layer;
transferring the second patterns into the to the additional layer hard mask layer by etching the to the additional layer hard mask layer through the first photosensitive layer; and
transferring the first and second patterns into the target layer by etching the target layer through the to the additional layer hard mask layer,
wherein the second patterns form lines of the to the additional layer hard mask layer, and the first patterns form trenches through the lines of the hard mask layer.

11. A method according to claim 10, comprising, after transferring the second patterns into the to the additional layer hard mask layer and before etching the target layer:
forming on the to the additional layer hard mask layer a second photosensitive layer having third patterns, and
transferring the third patterns into the to the additional layer hard mask layer by etching the to the additional layer hard mask layer through the third photosensitive layer,
the target layer being etched according to the first, second and third patterns formed in the hard mask layer, the third patterns forming lines of the target layer that are spaced apart by the first patterns.

12. A method according to claim 10, wherein:
depositing the first photosensitive layer includes directly depositing the first photosensitive layer on the to the additional layer hard mask layer;
forming second patterns in the first photosensitive layer includes transferring second patterns to the second photosensitive layer by exposing the second photosensitive layer to a beam of particles through a mask; and
the photosensitive layer has a reflection coefficient of the beam of particles lower than 1%, and a planar upper face, and covers the to the additional layer hard mask layer without trapping gas bubbles.

13. A method according to claim 12, wherein an upper surface of the first photosensitive layer has a height variation lower than 20%.

14. A method according to claim 10, further comprising:
depositing an additional layer onto the to the additional layer hard mask layer, the first photosensitive layer being deposited onto the additional layer; and
transferring the patterns formed in the first photosensitive layer to the additional layer by etching the additional layer.

15. A method according to claim 14, wherein:
forming second patterns in the first photosensitive layer includes transferring second patterns to the second photosensitive layer by exposing the second photosensitive layer to a beam of particles through a mask; and
the additional layer has a reflection coefficient of the beam of particles lower than 1%, and a planar upper face, and covers the to the additional layer hard mask layer without trapping gas bubbles.

16. A method according to claim 14, wherein an upper surface of the first photosensitive layer has a height variation lower than 20%.

17. A method according to claim 16, further comprising:
depositing a second hard mask layer on the additional layer, wherein the first photosensitive layer is deposited onto the second hard mask layer; and
transferring the patterns formed in the first photosensitive layer to the second hard mask layer by etching the second hard mask layer.

18. A method according to claim 10, wherein etching the target layer includes forming gates of CMOS transistors.

19. A method according to claim 10, wherein forming on the target layer the patterned first hard mask layer with first patterns includes:
depositing the first hard mask layer on a target layer;
depositing a second photosensitive layer on the first hard mask layer;
transferring the first patterns to the second photosensitive layer by exposing the second photosensitive layer to a beam of particles through a mask;
forming the first patterns in the second photosensitive layer;
transferring the first patterns into the first hard mask layer by etching the first hard mask layer through the second photosensitive layer.
